(19) United States
(12) Patent Application Publication
(10) Pub. No.: US 2002/0149382 A1
(43) Pub. Date: Oct. 17, 2002

(54) Distance change output device and method

(75) Inventor: Haruyuki Matsushita, Yokohama-shi (JP)

Correspondence Address: DARBY & DARBY P.C., 805 Third Avenue, New York, NY, 10022, US

(73) Assignee: Ando Electric Co., Ltd.

(21) Appl. No.: 10/118,652

(22) Filed: Apr. 8, 2002

(30) Foreign Application Priority Data
Apr. 12, 2001 (JP) P2001-114000

(51) Int. Cl. G01R 31/02

(52) U.S. Cl. 324/758

(57) ABSTRACT

In order to determine the time-series change in the distance between a probe head and a test head, a distance change output device comprising a distance sensor 6 which measures the distance between a probe card 3 of a wafer prober 1 and a test head 2 of a semiconductor integrated circuit testing device, a memory device 7a which stores distance values which are detected by the distance sensor 6 successively as time-series distance data, and an output device 7c which outputs the distance data which are stored in the memory device 7a as time-series list is provided.

### BACKGROUND OF THE INVENTION

1. Field of the Invention

The present invention relates to a distance change output device and to a method. The present invention particularly relates to a technique for outputting a measurement of a change in the distance between a test head of a semiconductor integrated circuit testing device and a probe card of a wafer prober.

2. Description of Related Art

In the case of a function test for a semiconductor integrated circuit in the form of a wafer, a wafer prober is used as a handling device. By combining this wafer prober and the semiconductor integrated circuit testing device, a function test of the semiconductor integrated circuit is performed. In this case, each pad of the semiconductor integrated circuit is made to come into electrical contact via probe cards in a wafer prober, and each terminal on the probe cards is connected to the connecting pins, in a contacting manner, which are disposed facing the probe cards.

The test head is arranged so as to move vertically closer to and away from the wafer prober which is disposed in a fixed manner, and the connecting pins are connected to each terminal on the probe cards in a contacting manner at a predetermined falling position. In the semiconductor integrated circuit testing device, the test head descending stop control section which controls the vertical movement of the test head and a distance sensor for measuring the distance between the probe card and the test head, the test head descending stop control section prevents the breakage of the probe card by controlling the distance between the probe card and the test head; in other words, the contacting pressure of the connecting pins towards the probe cards, according to the value measured by the distance sensor.

However, the test head may be as heavy as several hundred kilograms, and there is inevitably a difference between the stop position of the test head which is ordered by the test head descending stop control section and the actual stop position. Also, the amount of this difference continually changes due to deterioration of the motors. Also, in the case in which the DUT (device under testing) board is replaced, the test head is kept away from the probe card sufficiently. In this case, because the test head is driven by a different control section from the descending control section, the test head makes a rotating movement around the horizontal axis. Therefore, there is a possibility that the amount of the abovementioned gap and the relative positioning, such as the degree to which the probe card and the test head are parallel, will change.

### SUMMARY OF THE INVENTION

The present invention was made in consideration of the above problems, and an object of the present invention is to measure the continual change in the distance between the probe card and the test head and the change in the relative positioning of the probe card and the test head.

In order to achieve the above objects, in the present invention, as a first means according to the distance change output device, a device comprising a distance sensor which measures the distance between a probe card of a wafer prober 1 and a test head of a semiconductor integrated circuit testing device, a memory device which stores distance values which are measured by the distance sensor successively as a time-series distance data, and an output device which outputs the distance data which are stored in the memory device as time-series list is employed.

Also, as a second means according to the distance change output device, in the above first means, a distance change output device characterized in that the memory device and the output device are arranged as a test computer for managing the semiconductor integrated circuit testing device, the distance values which are measured by the distance sensor is loaded and stored in the memory device in the test computer as time-series distance data, and the distance value between the probe card and the test head are displayed in manner of a time-series list on the display of the test computer is employed.

As a third means according to the distance change output device, in the above first or second means, a device characterized in that a plurality of distance sensor are disposed in order to measure the distance of a plurality of points between the probe card and the test head, the measured value detected by the distance sensor are stored successively as a time-series distance data in the memory device, and the output device outputs the change of the relative positioning of wafer prober and the test head as compared to the coincident distance data is employed.

Also, in the present invention, as a first means according to the distance change output method, a means for storing the distance value detected by the distance sensor between a DUT board of the wafer prober and the test head of the semiconductor integrated circuit testing device successively as time-series distance data and for outputting the time-series change of the distance based on the distance data is employed.

As a second means according to the distance change output method, in the above first means, a means for storing the distance data by loading into the test computer which manages the semiconductor integrated circuit testing device and for displaying the list of distance data in the manner of a time-series by the test computer is employed.

As a third means according to the distance change output method, in the above first or second means, a means for displaying the list of the changes of the time-series relative positioning of the probe card and the test head is employed.

As explained above, because the distance change output device comprise a distance sensor which detects the distance between a probe card of a wafer prober and a test head of a semiconductor integrated circuit testing device, a memory device which stores distance values which are detected by the distance sensor successively as a time-series distance data, and an output device which outputs the distance data which are stored in the memory device as a time-series list, it is possible to obtain the time-series change of the distance between the probe card and the test head.

### BRIEF DESCRIPTION OF THE DRAWINGS

FIG. 1 is a view showing a structure of a distance change output device according to an embodiment of the present invention.

FIG. 2 is a block diagram showing a functional structure of the test head descending stop control section and a main structural part of an EWS (Engineering Work Station) according to an embodiment of the present invention.

FIG. 3 is an example of distance data according to an embodiment of the present invention.

### DETAILED DESCRIPTION OF THE INVENTION

An embodiment of the distance change output device and method according to the present invention is explained with reference to the drawings as follows.

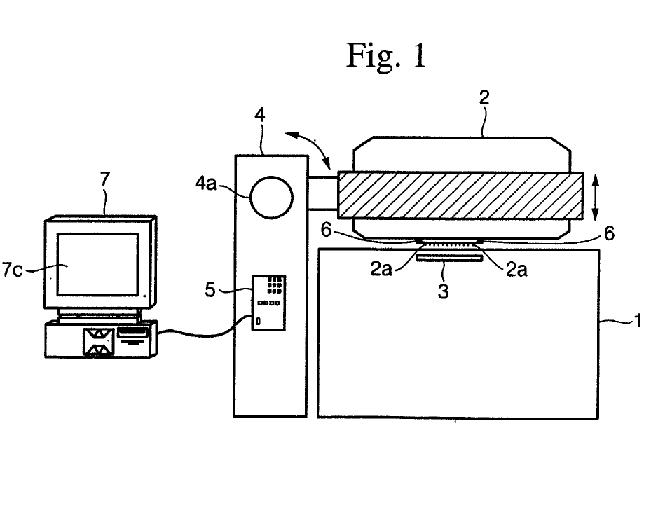

FIG. 1 is a view showing the structure of the distance change output device according to the present embodiment. In FIG. 1, reference numeral 1 indicates a wafer prober. Reference numeral 2 indicates a test head. Reference numeral 3 indicates a probe card. Reference numeral 4 indicates a reduction device. Reference numeral 5 indicates a test head descending stop control section. Reference numeral 6 indicates a distance sensor. Reference numeral 7 indicates an EWS. Among these structures, the distance change output device is made by combining the function of the distance sensor 6 and a part of the function of the test head descending stop control section 5 and a part of the function of the EWS 7. Additionally, among these structures, a test head 2, a reduction device 4, a test head descending stop control section 5, and a distance sensor 6 comprise a semiconductor integrated circuit testing device.

A wafer prober 1 is a handling device for semiconductor chips (semiconductor integrated circuit) in form of a wafer. By this wafer prober 1, probe contact pins implanted on the probe card 3 are contacted to each pad of the semiconductor chip, and each pad is then connected to the probe card 3.

A test head 2 is provided with a plurality of connecting pins 2a which are disposed on the above probe card 3 facing each other, and by descending to a predetermined position, each connecting pin 2a is contacted to be connected to the probe card 3. On a surface of a probe card 3, a plurality of electrodes are formed, and by contacting one of the above connecting pins 2a to each electrode, a semiconductor chip on the wafer prober 1 electrically contacts a semiconductor integrated circuit testing device including a test head 2.

A reduction device 4 supports the above test head 2 so as to be able to move freely in the vertical direction. The reduction device 4 also moves the test head 2 vertically around an axis 4a which is a direction towards and away from the probe card 3 when a DUT board 3 is replaced. A test head descending stop control section 5 controls the vertical movement of the test head 2, and is connected to EWS 7 via a serial bus such as RS-232C.

A distance sensor 6 is provided on the test head 2 and measures the distance between the test head 2 and the DUT board 3. The distance sensor 6 also outputs the detected value to the test head descending stop control section 5. A plurality of the distance sensors 6 are provided so as to be able to detect a plurality of points (for example, 3 points) of the test head 2 and the probe card 3, and each distance sensor 6 outputs each detected value to the test head descending stop control section 5.

Here, an object of providing a plurality of distance sensors 6 is to measure the distance between the test head 2 and the probe card 3 more precisely and to determine the relative positioning such as inclination of the test head 2 relative to the probe card 3. Additionally, as a distance sensor 6, a laser distance measuring device which can obtain micrometer order of precision is used.

An EWS 7 is a test computer which is subordinately provided to the semiconductor integrated circuit testing device for the purpose of managing the semiconductor integrated circuit testing device, and is connected to the semiconductor integrated circuit testing device electrically. The EWS 7 edits a test program for testing the function of, for example, a semiconductor chip and transmits to the semiconductor integrated circuit testing device, or acquires the testing data from the semiconductor integrated circuit testing device.

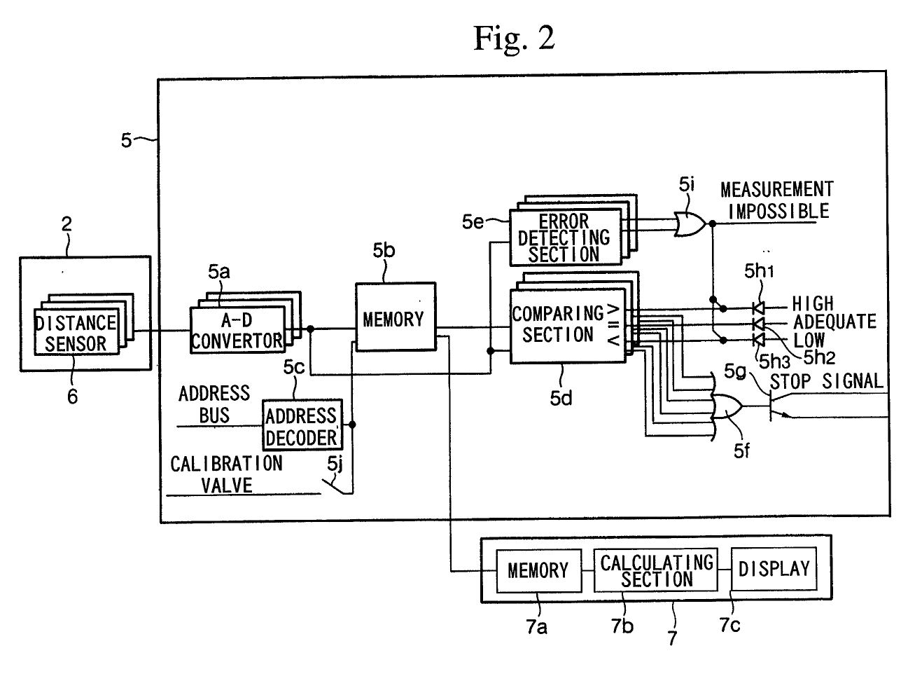

Next, FIG. 2 is a block diagram showing the function structure of the above test head descending stop control section 5 and the main function structure of the EWS 7. In the test head descending stop control section 5, reference numeral 5a indicates an A-D converter, reference numeral 5b indicates a memory (storage device). Reference numeral 5c indicates an address decoder. Reference numeral 5d indicates a comparing section. Reference numeral 5e indicates an error detecting section. Reference numeral 5f indicates an OR gate. Reference numeral 5g indicates a driver. Reference numerals 5h1 to 5h3 indicate LEDs (light emission diode). Reference numeral 5i indicates an OR gate. Also reference numeral 5j indicates a switch. Also, in EWS 7, reference numeral 7a indicates a memory. Reference numeral 7b indicates a calculating section. Reference numeral 7c indicates a display (output device). Among these structures, an A-D converter 5a, a memory 5b, an address decoder 5c, a memory 7a, a calculating section 7b, and a display 7c comprise the distance change output device.

Three A-D converters 5a are provided corresponding to the distance sensors 6, and A-D converters convert the detected value (analog signal) which are input by each distance sensor 6 to digital signals by performing sampling at a predetermined time interval and outputs to the memory 5b. A memory 5b stores the above digital signal (detected distance value) as detected data in the address successively designated by the address decoder 5c, and also stores the calibration value which is input via the switch 5j.

The comparing section 5d compares a calibration value which is read out by this memory 5b to the detected distance value which is input from the A-D converter 5a mutually and outputs the result the comparison such as coincident or not-coincident to the OR gate 5f, and drives the LEDs 5h1 to 5h3 according to the result of comparison. The error detecting section 5e searches abnormalities of the measured distance value (such as abnormally close and abnormally distant) which is input from the A-D converter 5a, and outputs the result of the detection to the OR gate 5i. The OR gate 5i notifies the situation such as “abnormally close” or “abnormally distant” to outer structures as impossible measurements which are deviations of the detected value out of the tolerable range for measurement by the distance sensor 6.

On the other hand, OR gate 5f picks up the logical sum of the result of the comparison at the comparing section 5d, and drives the driver 5g according to the logical result. Only when the above measured distance value is equal to the adequate distance, the output will be converted. The driver 5g gives an instruction to the driving circuit of the servo motor (not shown in the drawing) which moves the test head vertically to stop the descending of the test head 2. If the output of the OR gate 5f is converted, the driver 5g outputs the signal for stopping the descending movement. LEDs 5h1 to 5h3 display the status (such as “high”, “adequate”, or “low”) of the stopping position of the test head 2 according to the result of comparison at the comparing section 5d.

Switch 5j is closed when a calibration value which is an adequate distance between the test head 2 and the probe card 3 is written into the memory 5b. The calibration (revision) of above adequate distance is performed at the time of periodical inspection such as biannually or annually, the calibration value based on such revision is input into the memory 5b via the switch 5j at this time.

In this structural operation, the distance (stoppage error) from the time of the output of the above stopping signal time by the driver 5g to the time of actual stopping of the descending of the test head 2 is measured by using the distance sensor 6. The above calibration value is equal to the distance value obtained by deducting the stoppage error from the adequate distance between the test head 2 and the DUT board 3. That is, the adequate distance between the test head 2 and the probe card 3 is realized by adjusting the output timing of the above stopping signal according to the standard such as the calibration value.

Consequently, in EWS 7, the structural elements relating to the distance change output device are a memory 7a, a calculating section 7b, and a display 7c. A memory 7a adds a time stamp to a measured value which is loaded from the memory 5b inside the above test head descending stop control section 5, and successively stores such values as time-series distance data. A calculating section 7b reads out the distance data and the time stamp from the memory 7a, and outputs the distance data and the time stamp to the display 7c with a predetermined image format. The display 7c displays the above distance data and the time stamp.

Next, the operation of the distance change output device with such a construction is explained in detail.

First, inherent functional movement of the test head descending stop control section 5 is explained in detail. When the test head 2 is descended to be positioned at the proper position relative to the probe card 3, the detected distance value of the distance sensor 6 is converted to digital signals (detected value) by the A-D converter 5a, and the detected distance value of the distance sensor 6 is supplied to the comparing section 5d. Also, the calibration value is read out from the memory 5b and is supplied to the comparing section 5d. The comparing section Sd compares the above detected distance value which is gradually reduced along with the descending of the test head 2 to the calibration value successively. Also, in the OR gate Sf, when the calibration value and the detected distance value coincide, the output is converted; thus, the stopping signal is output, and the test head 2 stops in a position with an adequate distance to the probe card 3.

On the other hand, in the test head descending stop control section 5, by designating the write-in address successively by the address decoder Sc, the detected distance value of the distance sensor 6 is stored in the memory 5b successively. When memory 5b overflows, the address decoder 5c designates the top address; therefore the measured distance value is stored in the memory 5b successively. In this way, the latest measured distance value of the distance sensor 6 is always stored in the memory 5b.

To such memory 5b, when collecting commands which instruct the collecting of the detected distance value is input into the EWS 7, the latest detected value of the distance which is stored in the above memory 5b is loaded in the memory 7a inside the EWS 7 as time-series distance data together with the time stamp. This distance data is written in the address which is next to the distance data stored in the past; thus, the distance data of each time frame is written in consecutive addresses from the older data successively.

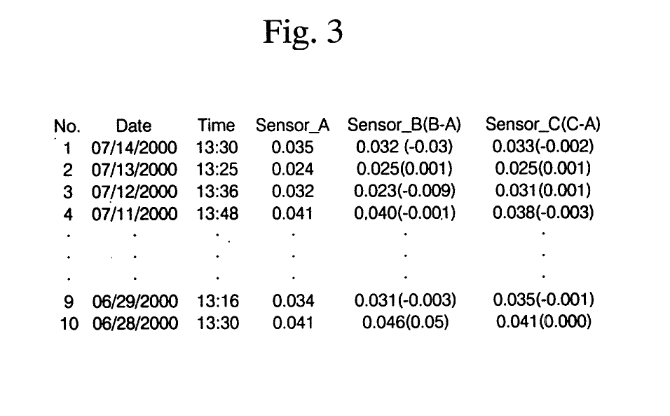

Additionally, the display command which instructs displaying the distance data on the EWS 7 is put in, as explained above, the distance data which is written in the memory 7a is read out successively in order of address by the calculating section 7b and is put out to the display 7c and displayed as a time-series list. FIG. 3 is an example of displaying the distance data in the display 7c. In this case of the displaying example, the detected value (μm) of three distance sensors 6 (Sensor A, Sensor B, and Sensor C) is displayed in order of time-series with the time stamp (data, time). Also, the variance (B-A, C-A) of each detected value of the Sensor B and the Sensor C to the detected value of Sensor A is displayed as a relative position of the test head 2 against the probe card 3.

That is, from the listed display of such detected values, time-series change of the distance between the probe card 3 and the test head 2 can be read out easily, and the time-series change of the relative position of the test head 2 against the probe card 3 can also be read out easily. Therefore, because the trend of the change of the distance and the relative positioning between the test head 2 and the probe card 3 can be obtained, the breakage of the probe card 3 can be prevented, and the updating period of the above calibration value can be optimized.

Additionally, in the above FIG. 3, although the detected value is loaded into the memory 7a of EWS 7 every day, the time necessary to collect the detected value can be set randomly, because the collecting command is put into the EWS 7. For example, the detected value can be collected every two days or every weeks according to the trend of change of the above distance and the relative positioning.

Also, in the above embodiment, although the measured distance value of the distance sensor 6 is loaded into the EWS 7 as a test computer and is displayed, the present invention is not limited to such a case. Furthermore, the output device of the present invention is not limited to the display 7c of the EWS 7, and the measured distance value may also be printed out as a list by a printer in place of the display 7c.

What is claimed is:

1. A distance change output device comprising:
a distance sensor which measures the distance between a probe card of a wafer prober and a test head of a semiconductor integrated circuit testing device;
a memory device which stores distance values which are measured by the distance sensor successively as time-series distance data; and
an output device which outputs the distance data which are stored in the memory device as time-series list.

2. A distance change output device according to claim 1, wherein
the memory device and the output device are arranged as a test computer for managing the semiconductor integrated circuit testing device;
the distance values which are detected by the distance sensor are loaded and stored in the memory device in the test computer as time-series distance data; and
the distance value between the probe card and the test head are displayed in a time-series list on the display of the test computer.

3. A distance change output device according to claim 1, wherein;
a plurality of distance sensors are disposed in order to measure the distance of a plurality of points between the probe card and the test head;
the detected values detected by the distance sensor are stored successively as time-series distance data in the memory device; and
the output device outputs the change of the relative positioning of wafer prober and the test head as compared to the coincident distance data.

4. A distance change output device according to claim 2, wherein;
a plurality of distance sensors are disposed in order to measure the distance of a plurality of points between the probe card and the test head;
the detected values detected by the distance sensor are stored successively as time-series distance data in the memory device; and
the output device outputs the change of the relative positioning of wafer prober and the test head as compared to the coincident distance data.

5. Distance change output method comprising:
detecting the distance value between a DUT board of the wafer prober and the test head of the semiconductor integrated circuit testing device measured by the distance sensor;
storing the data of distance value successively as time-series distance data; and
outputting the time-series change of the distance based on the distance data.

6. Distance change output method according to claim 5 further comprising:
storing the distance data by loading into the test computer which manages the semiconductor integrated circuit testing device; and
displaying the list of distance data in a time-series by the test computer.

7. Distance change output method according to claim 5 for displaying the list of the change of time-series relative positioning of the probe card and the test head.

8. Distance change output method according to claim 6 for displaying the list of the change of time-series relative positioning of the probe card and the test head.
